(19) United States
(12) Patent Application Publication
(10) Pub. No.: US 2016/0093391 A1
(43) Pub. Date: Mar. 31, 2016

(54) SEMICONDUCTOR DEVICE

(71) Applicant: SK hynix Inc., Icheon-si Gyeonggi-do (KR)

(72) Inventor: Jung Woon SHIM, Incheon (KR)

(21) Appl. No.: 14/620,418

(22) Filed: Feb. 12, 2015

(30) Foreign Application Priority Data
Sep. 29, 2014 (KR) 10-2014-0130370

(51) Int. Cl. G11C 16/26; G11C 16/24; G11C 16/04; G11C 16/34

(52) U.S. Cl. CPC G11C 16/26; G11C 16/3436; G11C 16/24; G11C 16/0483

(57) ABSTRACT

A semiconductor device may include a memory string coupled between a bit line and a common source line and configured to include a drain select transistor, memory cells, and a source select transistor. The drain select transistor may be configured to operate based on a voltage applied to a drain select line. The memory cells may be configured to operate based on a voltage applied to word lines. The source select transistor may be configured to operate based on a voltage applied to a source select line. The semiconductor device may include an operation circuit configured to perform a read operation or a verify operation of the memory cells. The operation circuit may be configured to apply a negative voltage to the common source line during the read operation or the verify operation.

### CROSS-REFERENCE TO RELATED APPLICATION

The present application claims priority to Korean patent application number 10-2014-0130370 filed on Sep. 29, 2014, in the Korean Intellectual Property Office, the entire disclosure of which is incorporated by reference herein.

### BACKGROUND

1. Technical Field

The present disclosure generally relates to a semiconductor device. More specifically, the present disclosure relates to a semiconductor device including a memory cell.

2. Related Art

A read operation may be used to output data stored in a memory cell. A program operation may be used for storing data in the memory cell. After a program operation, a verify operation may be performed to determine if the data was stored in the memory cell.

The read operation or the verify operation is performed through a method of sensing the voltage variation of a bit line after the bit line of the memory cell is precharged and a read voltage or a verify voltage is applied to the memory cell.

In order to increase accuracy of the read operation or the verify operation, an operation condition is set to provide enough current flowing through the memory cell. Thus, a high precharge voltage is applied to the bit line. However, the amount of the current flowing through the memory cell is difficult to increase by using only the application of applying only the high precharge voltage to the bit line.

### SUMMARY

In an embodiment, a semiconductor device may include a memory string coupled between a bit line and a common source line and configured to include a drain select transistor, memory cells, and a source select transistor. The drain select transistor may be configured to operate based on a voltage applied to a drain select line. The memory cells may be configured to operate based on a voltage applied to word lines. The source select transistor may be configured to operate based on a voltage applied to a source select line. The semiconductor device may include an operation circuit configured to perform a read operation or a verify operation of the memory cells. The operation circuit may be configured to apply a negative voltage to the common source line during the read operation or the verify operation.

In an embodiment, a semiconductor device may include a memory string including memory cells coupled between a bit line and a common source line. The semiconductor device may include an operation circuit configured to perform a precharge operation for precharging the bit line, an evaluation operation for applying an operating voltage to the memory cells, and a sensing operation for sensing a voltage variation of the bit line. The operation circuit may be configured to apply a negative voltage to the common source line during the sensing operation.

In an embodiment, a semiconductor device may include a first vertical channel layer coupled between a pipe channel layer and a common source line. The semiconductor device may include a plurality of first conductive layers located between the pipe channel layer and the common source line and surrounding the first vertical channel layer at different heights of the first vertical channel layer forming at least one memory cell. The semiconductor device may include a second vertical channel layer coupled between the pipe channel layer and a bit line. The semiconductor device may include a plurality of second conductive layers located between the pipe channel layer and the bit line and surrounding the second vertical channel layer at different heights of the second vertical channel layer forming at least one memory cell. A negative voltage may be applied to the common source line during a read operation or a verify operation of the at least one memory cell.

### BRIEF DESCRIPTION OF THE DRAWINGS

FIG. 1 is a block diagram illustrating a representation of a semiconductor device according to an embodiment.

FIGS. 2A and 2B are views illustrating a representation of a memory string according to an embodiment.

FIG. 3 is a view illustrating a representation of a memory block according to an embodiment.

FIGS. 4A and 4B are views illustrating a representation of a memory string according to an embodiment.

FIG. 5 is a circuit diagram illustrating a representation of a read/write circuit according to an embodiment.

FIG. 6 is a waveform diagram illustrating a representation of a memory system according to an embodiment.

FIG. 7 is a block diagram illustrating a representation of a memory system according to an embodiment.

FIG. 8 is a block diagram illustrating a representation of a fusion memory device or a representation of a fusion memory system configured to perform a program operation according to the above-mentioned embodiments.

FIG. 9 is a block diagram illustrating a representation of a computing system including a flash memory device 912 according to an embodiment.

### DETAILED DESCRIPTION

Hereinafter, best modes of the present invention will be explained. In the drawings, the thicknesses of layers and regions are expressed for convenience of the explanation, and may be exaggerated with respect to an actual physical thickness. In the explanation, a well known structure, which is not related to the scope of the application, may be omitted. In numbering reference numerals to the structural parts of each drawing, like numerals may refer to like elements throughout the description of the figures although the reference numerals are displayed in different drawings.

The present application may be directed to a semiconductor device capable of improving operation characteristics.

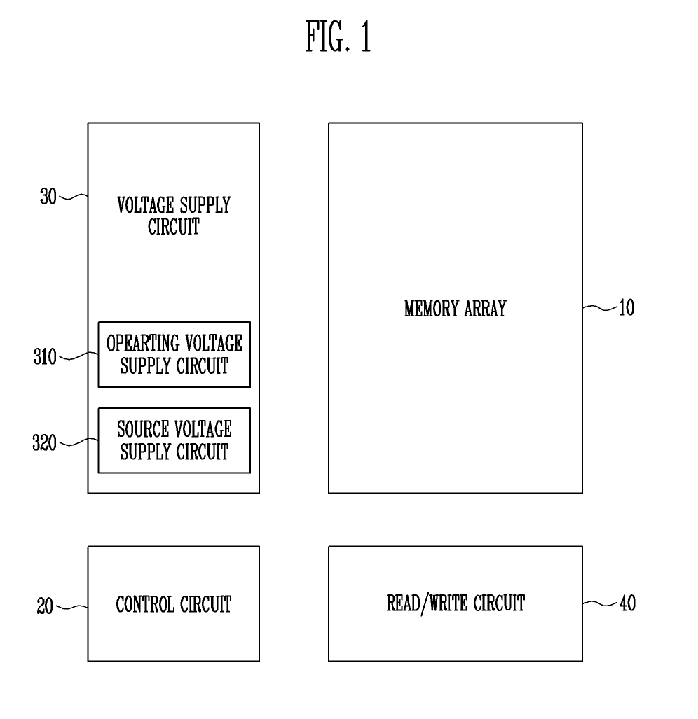

FIG. 1 is a block diagram illustrating a representation of a semiconductor device according to an embodiment.

Referring to FIG. 1, the semiconductor device may include a memory array 10 and operation circuits 20 to 40. The memory array 10 may include a plurality of memory blocks (not illustrated). Each of the memory blocks may include a plurality of memory strings (not illustrated). Each of the memory strings may include a plurality of memory cells (not illustrated). In a flash memory device, a memory block may include flash memory cells. For example, the memory block may include flash memory cells including a floating gate formed of polysilicon or a charge trap layer formed of a nitride.

In particular, the memory block may include memory strings connected or coupled to bit lines (not illustrated), respectively, and connected or coupled to a common source line (not illustrated) in parallel. The memory strings may be formed in a 2-dimensional structure or a 3-dimensional structure on a semiconductor substrate. A memory block including the memory string of the 3-dimensional structure will be explained below.

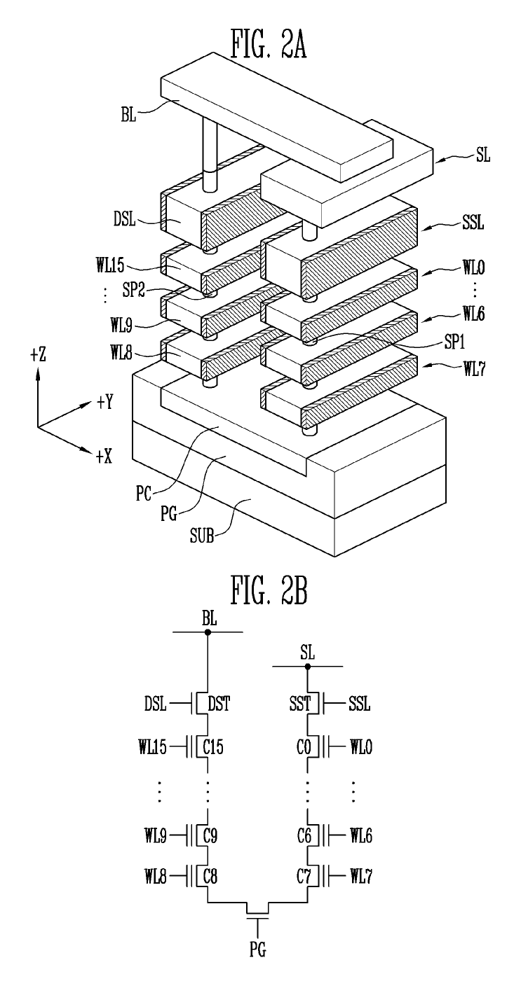

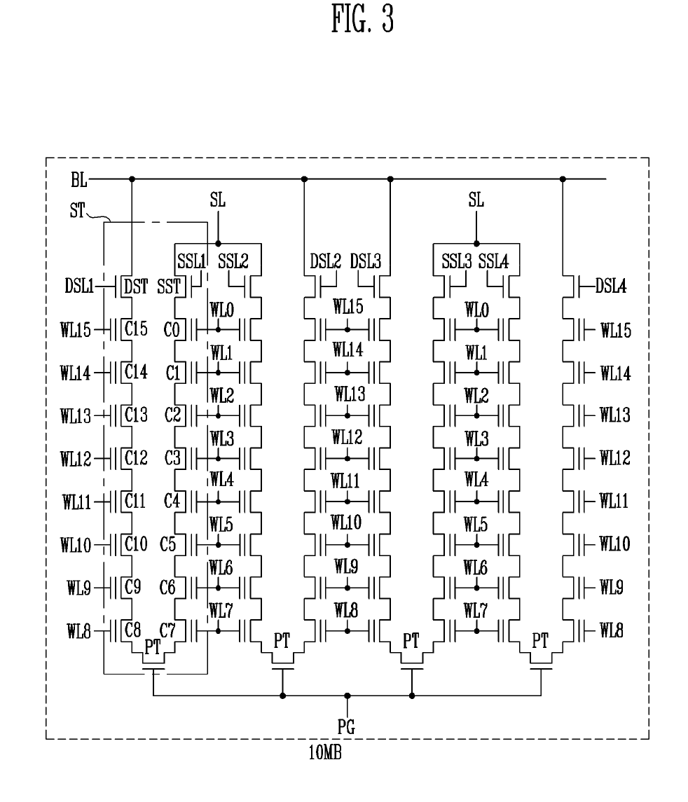

FIGS. 2A and 2B are views illustrating a representation of a memory string according to an embodiment.

Referring to FIGS. 2A and 2B, a pipe gate PG, including a recessed part, may be formed on a semiconductor substrate SUB, and a pipe channel layer PC may be formed in the recessed part of the pipe gate PG. A plurality of vertical channel layers SP1 and SP2 are formed on the pipe channel layer PC. An upper portion of the first vertical channel layer SP1 among the pair of the vertical channel layers SP1 and SP2 may be connected or coupled to a common source line SL, and an upper portion of the second vertical channel layer SP2 may be connected or coupled to a bit line BL. The vertical channel layers SP1 and SP2 may be formed of polysilicon.

A plurality of conductive layers DSL and WL15 to WL8 are formed to surround the second vertical channel layer SP2 at different heights of the second vertical channel layer SP2. Also, a plurality of conductive layers SSL and WL0 to WL7 are formed to surround the first vertical channel layer SP1 at different heights of the first vertical channel layer SP1. A multi-layered layer (not illustrated) including a charge trap layer is formed on surfaces of the vertical channel layers SP1 and SP2 and a surface of the pipe channel layer PC. A multi-layered layer may also be interposed between the vertical channel layers SP1 and SP2 and the conductive layers DSL, WL15 to WL8, SSL, and WL to WL7 and between the pipe channel layer PC and the pipe gate PG.

The uppermost conductive layer surrounding the second vertical channel layer SP2 may become a drain select line DSL, and the conductive layers under the drain select line DSL may become word lines WL15 to WL8. The uppermost conductive layer surrounding the first vertical channel layer SP1 may become a source select line SSL, and the conductive layers under the source select line SSL may become word lines WL0 to WL7.

In other words, the first conductive layers SSL and WL0 to WL7 and the second conductive layers DSL and WL15 to WL8 each are stacked on different areas of the semiconductor substrate. The first vertical channel layer SP1 passing through the first conductive layers SSL and WL0 to WL7 is vertically connected or coupled between the common source line SL and the pipe channel layer PC. The second vertical channel layer SP2 passing through the second conductive layers DSL and WL15 to WL8 is vertically connected or coupled between the bit line BL and the pipe channel layer PC.

A drain select transistor DST is formed at a portion where the drain select line DSL surrounds the second vertical channel layer SP2, and memory cells C15 to C8 are respectively formed at portions where the word lines WL15 to WL8 surround the second vertical channel layer SP2. A source select transistor SST is formed at a portion where the source select line SSL surrounds the first vertical channel layer SP1, and memory cells C0 to C7 are respectively formed at portions where the word lines WL0 to WL7 surround the first vertical channel layer SP1.

According to the above-mentioned structure, the memory string ST may include the drain select transistor DST and the memory cells C15 to C8 vertically connected or coupled to the substrate between the bit line BL and the pipe gate PG, the source select transistor SST vertically connected or coupled to the substrate between memory cells C0 and C7, the common source line SL, and the pipe gate PG.

The above examples implement sixteen main word lines WL0 to WL15, however, the number of the main word lines may be changed and the embodiments are not limited in this manner. Also, dummy word lines (not illustrated) may further be respectively formed between the drain select line DSL and the word line WL15 and between the source select line SSL and the word line WL0. That is, dummy memory cells may further be respectively connected or coupled between the drain select transistor DST and the memory cell C7 and between the source select transistor SST and the memory cell C0.

FIG. 3 is a view illustrating a representation of a memory block according to an embodiment.

Referring to FIG. 3, the memory block 10MB may include a plurality of memory strings ST connected or coupled to bit lines. Each of the memory strings ST may include a U-shaped structure and may include a pipe transistor PT. Each of the memory strings ST may include a first vertical memory string including elements SST and C0 to C7 vertically connected or coupled between the common source line SL and the pipe transistor PT, and a second vertical memory string including elements DST and C15 to C8 vertically connected or coupled between the bit line BL and the pipe transistor PT. The pipe transistor and memory strings may be formed on a substrate. The first vertical memory string SST and C0 to C7 may include a source select transistor SST and memory cells C0 to C7. The source select transistor SST is controlled by a voltage applied to a source select line SSL1. The memory cells C0 to C7 are controlled by voltages applied to word lines WL0 to WL7. The word lines WL0 to WL7 may be stacked. The second vertical memory string DST and C15 to C8 may include a drain select transistor DST and memory cells C8 to C15. The drain select transistor DST is controlled by a voltage applied to a drain select line DSL1. The memory cells C8 to C15 are controlled by voltages applied to word lines WL8 to WL15. The word lines WL8 to WL15 may be stacked

When the memory block 10MB is selected, the pipe transistor PT connected or coupled between a pair of memory cells C7 and C8 disposed at substantially a center of the memory string of the U-shaped structure performs an operation electrically connecting channel layers of the first vertical memory string SST and C0 to C7 included in the selected memory block 10MB to channel layers of the second vertical memory string DST and C15 to C8.

In a memory block with the 2-dimensional structure, one memory string is connected or coupled to every bit line and the drain select transistors of the memory block are simultaneously controlled by one drain select line. However, in the memory block 10MB with the 3-dimensional structure, a plurality of the memory strings ST may be commonly connected or coupled to each bit line BL. In the same memory block 10MB, the number of the memory strings ST, which are commonly connected or coupled to one bit line BL and controlled by the same word lines, may be changed based on a design.

The plurality of memory strings may be connected or coupled to one bit line BL in parallel. The drain select transistors DST are independently controlled by select voltages applied to the drain select lines DSL1 to DSL4 to selectively connect or coupled one bit line BL to the memory strings ST.

The memory cells C0 to C7 of the first vertical memory string including elements SST and C0 to C7, and the memory cells C8 to C15 of the second vertical memory string including elements DST and C15 to C8 are respectively controlled by operating voltages applied to the stacked word lines WL0 to WL15. The above word lines WL0 to WL15 may be classified in a memory block unit.

The select lines DSL0 to DSL4 and SSL0 to SSL4 and the word lines WL0 to WL15 become local lines of the memory block 10MB. The source select lines SSL0 to SSL4 and the word lines WL0 to WL7 may become local lines of the first vertical memory string. The drain select lines DSL0 to DSL4 and the word lines WL15 to WL8 may become local lines of the second vertical memory string. Gates PG of the pipe transistors PT may be commonly connected or coupled in the memory block 10MB.

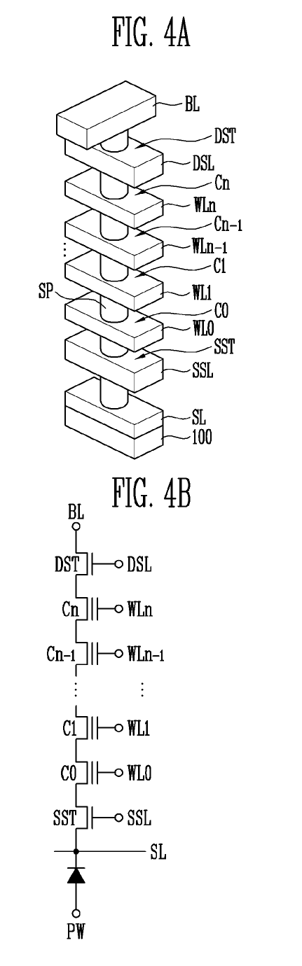

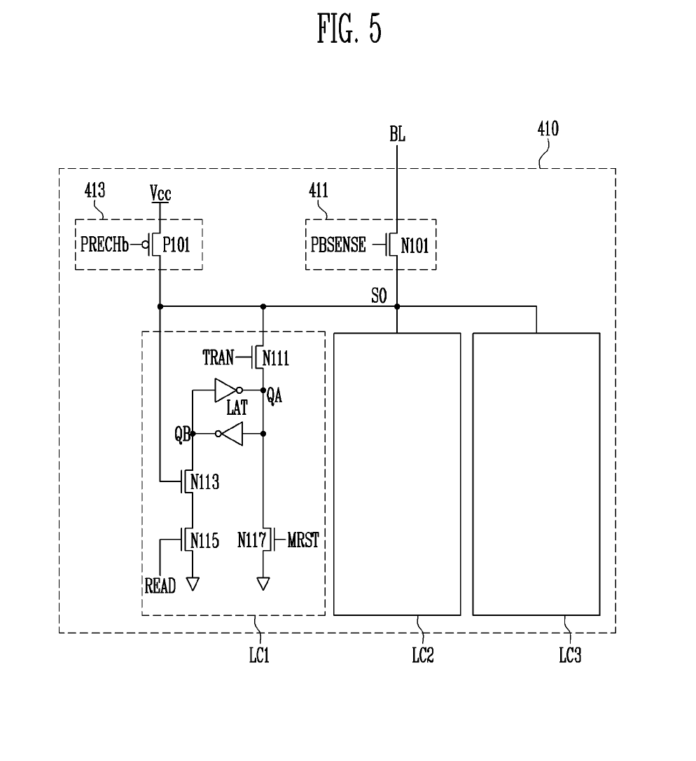

FIGS. 4A and 4B are views illustrating a representation of a memory string according to an embodiment.

Referring to FIGS. 4A and 4B, a common source line SL is formed on a semiconductor substrate 100 on where a P-well PW is formed. A vertical channel layer SP is formed on the common source line SL. An upper portion of the vertical channel layer SP is connected or coupled to a bit line BL. The vertical channel layer SP may be formed of polysilicon. A plurality of conductive layers SSL, WL0 to WLn, and DSL may be formed at different heights of the vertical channel layer SP to surround the vertical channel layer SP. A multilayered layer (not illustrated) including a charge trap layer is formed on a surface of the vertical channel layer SP. The multilayered layer is interposed between the vertical channel layer SP and the conductive layers SSL, WL0 to WLn, and DSL.

A lowermost conductive layer becomes a source select line (or a first select line) SSL, and an uppermost conductive layer becomes a drain select line (or a second select line) DSL. Conductive layers between the select lines SSL and DSL become word lines WL0 to WLn. In other words, the conductive layers SSL, WL0 to WLn, and DSL are formed as a multilayer on a semiconductor substrate, and the vertical channel layer SP passing through the conductive layers SSL, WL0 to WLn, and DSL is vertically connected or coupled between the bit line BL and the source line SL formed on the semiconductor substrate.

A drain select transistor (or a second select transistor) DST is formed on a portion where the uppermost conductive layer DSL surrounds the vertical channel layer SP, and a source select transistor (or a first select transistor) SST is formed on a portion where the lowermost conductivity layer SSL surrounds the vertical channel layer SP. Memory cells C0 to Cn are formed on portions where the central conductive layers WL0 to WLn surround the vertical channel layer SP.

According to the above structure, the memory string may include the source select transistor SST, the memory cells C0 to Cn, and the drain select transistor DST between the common source line SL and the bit line BL. The source select transistor SST, the memory cells C0 to Cn, and the drain select transistor DST between the common source line SL and the bit line BL may all be vertically connected or coupled to the substrate. The source select transistor SST electrically connects or couples the memory cells C0 to Cn to the common source line SL based on a first select signal. The first select signal may be applied to the first select line SSL. The drain select transistor DST electrically connects or couples the memory cells C0 to Cn to the bit line BL based on a second select signal. The second select signal may be applied to the second select line DSL.

Referring again to FIGS. 1 and 2B, the operation circuits 20 to 40 may be configured to perform a program loop, an erase loop, and a read operation of memory cells (for example, C0) connected or coupled to a selected word line (for example, WL0). The program loop may include a program operation and a verify operation, and the erase loop may include an erase operation and a verify operation. The operation circuits 20 to 40 may perform a program operation (or a post program operation) to adjust an erase level in which threshold voltages of memory cells are distributed after the erase loop.

In order to perform the program loop, the erase loop, and the read operation, the operation circuits 20 to 40 are configured to selectively output operating voltages to local lines SSL, WL0 to WL15, PG, and DSL of the selected memory block and the common source line SL, and control precharge/discharge of the bit lines BL or sense a current flow (or a voltage variation) of the bit lines BL.

In a NAND flash memory device, the operation circuits may include a control circuit 20, a voltage supply circuit 30, and a read/write circuit 40. Each of the above circuits will be explained below.

The control circuit 20 may control the voltage supply circuit 30 to generate operating voltages. The operating voltages may be used to perform the program loop, the erase loop, and the read operation. The program loop, the erase loop, and the read operation may be performed in response to a command signal input from the outside, or outside of the semiconductor device. The voltage supply circuit 30 may generate operating voltages at desired levels and may be configured to apply the operating voltages to the local lines SSL, WL0 to WL15, PG, and DSL and the common source line SL of the selected memory block. Also, the control circuit 20 controls the read/write circuit 40 to control precharge/discharge of the bit lines BL based on data to be stored in the memory cells to perform the program loop, the erase loop, and the read operation, or sense a current flow (or a voltage variation) of the bit lines BL during the read operation or verify operation.

The voltage supply circuit 30 generates the operating voltages required in the program loop, the erase loop, and the read operation of the memory cells based on the control of the control circuit 20. For example, the operating voltages may include a program voltage, a read voltage, an erase voltage, a pass voltage, a select voltage, a common source voltage, and/or the like. The voltage supply circuit 30 may output the operating voltages to the local lines SSL, WL0 to WL15, PG, and DSL and the common source line SL of the selected memory block in response to a row address signal (not illustrated) of the control circuit 20. An operating voltage supply circuit 310 of the voltage supply circuit 30 may supply operating voltages to the local lines SSL, WL0 to WL15, PG, and DSL of the selected memory block. A source voltage supply circuit 320 may apply operating voltages including negative voltages to the common source line SL.

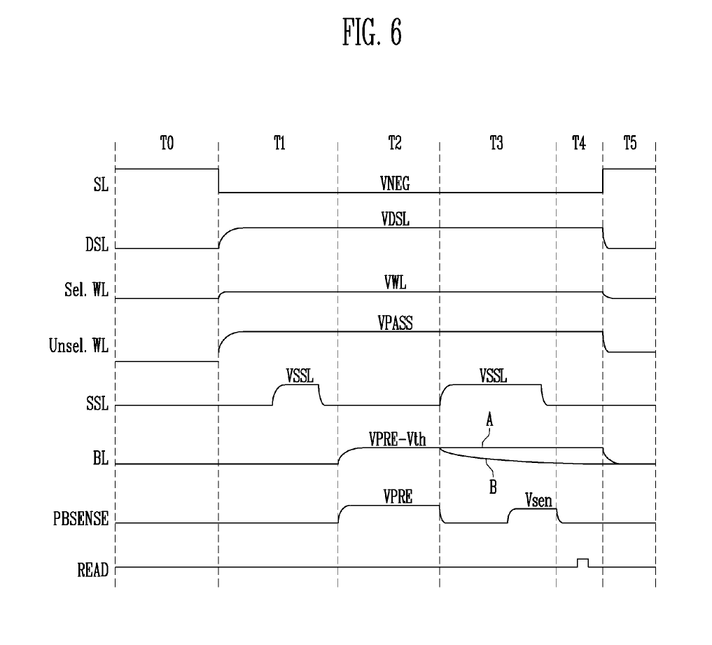

The read/write circuit 40 may include a plurality of page buffers (PBs) 410 (illustrated in FIG. 5) respectively connected or coupled to the memory array 10 through the bit lines BL. The PBs may be connected or coupled to the bit lines BL, respectively. That is, one PB may be connected or coupled to one bit line. In the program operation, the PBs selectively precharge the bit lines BL based on a control signal of the control circuit 20 and data to be stored in the memory cells. In the program verify operation or the read operation, the read/write circuit 40 precharges the bit lines BL based on the control of the control circuit 20, and then senses the voltage variation or a current of the bit lines BL and latches data read from the memory cell.

FIG. 5 is a circuit diagram illustrating a representation of a read/write circuit according to an embodiment.

Referring to FIG. 5, a PB of the read/write circuit may operate based on control signals received from a control circuit, and signals PRECHb, TRAN, MRST, PBSENSE, and READ explained hereinafter may be included in control signals outputted from a control circuit.

The PB may include a bit line connection circuit 411, a precharge circuit 413, and a plurality of latch circuits LC1 to LC3.

The bit line connection circuit 411 performs an operation of connecting or coupling the bit line BL to one latch circuit of latch circuits LC1 to LC3 in response to a connect signal PBSENSE. The bit line connection circuit 411 may include a switching device N101 configured to operate in response to the connect signal PBSENSE. The the latch circuits LC1 to LC3 are connected or coupled to the switching device N101 in parallel. A connection node between the bit line connection circuit 411 and the latch circuits LC1 to LC3 is a sensing node SO. The bit line connection circuit 411 performs an operation of connecting or coupling the bit line BL to the sensing node SO in response to the connect signal PBSENSE.

The precharge circuit 413 may include a switching device P101. The switching device P101 may be connected or coupled between a power voltage terminal and the sensing node SO and configured to operate in response to a precharge signal PRECHb. A voltage Vcc precharging the sensing node SO may be used as a precharge voltage to precharge the bit line BL. The precharge circuit 413 may generate the precharge voltage to precharge the bit line BL.

The number of the latch circuits LC1 to LC3 may be changed based on a design, and examples including three latch circuits LC1 to LC3 will be explained. Generally, only one of the latch circuits LC1 to LC3 is activated. That is, one of the latch circuits LC1 to LC3 is electrically connected or coupled to the sensing node SO.

The first latch circuit LC1 may temporarily store data stored in the memory cell in response to a voltage of the bit line during the read operation. The first latch circuit LC1 may perform an operation of transmitting the data to the third latch circuit LC3. The second latch circuit LC2 may perform an operation of latching a comparison result value between a threshold voltage of the memory cell and a desired voltage and outputting a comparison result signal corresponding to the comparison result value during the verify operation performed after the program operation. The third latch circuit LC3 may be used as a cache latch circuit for temporarily storing data inputted from the outside and transmitting the data to the other latch circuits LC1 or LC2. The third latch circuit LC3 may be used to temporarily store data read from the memory cell by the read operation. The date read with the read operation may be outputted to the outside. The third latch circuit LC3 may perform an operation of applying a program prohibition voltage or a program permission voltage to the bit line during the program operation based on data transmitted from the second latch circuit LC2.

Each of the latch circuits LC1 to LC3 may include a plurality of switching devices and a latch. The first latch circuit LC1 will be explained as an example.

The first latch circuit LC1 may include a latch LAT configured to latch data, a switching element N111 configured to connect a non-inversion terminal QA of the latch LAT to the sensing node SO in response to a transmission signal TRAN, and a switching element N113 connected or coupled to an inversion terminal QB of the latch LAT and operated based on a voltage of the sensing node SO. The first latch circuit LC1 may include a switching element N115 connected or coupled between the switching element N113 and a ground terminal and operated based on a read signal READ. The first latch circuit LC1 may include a switching element N117 connected or coupled between the non-inversion terminal QA of the latch LAT and the ground terminal and operated in response to a reset signal MRST.

Since signals of different waveforms are applied to the other latch circuits LC2 and LC3, only one latch circuit may be activated or perform different functions from each other although the latch circuits LC1 to LC3 are configured to be the same structure or substantially the same structure.

Hereinafter, an operation of a semiconductor device including the above structures will be explained. FIG. 6 is a waveform diagram illustrating a representation of a memory system according to an embodiment.

Referring to FIGS. 2B, 5, and 6, all of the lines are set to be an initial state in a stand-by period T0. That is, a ground voltage is applied to the select lines DSL and SSL, the word lines Sel. WL and Unsel. WL, the bit line BL, and the common source line SL. The connection signal PBSENSE and the read signal READ are applied to the PB 410 at a low level.

Then, the operation circuit performs a read operation or a verify operation while a negative voltage VNEG is applied to the common source line SL.

In a first period T1, before performing the read operation or the verify operation, the operation circuit may apply a negative voltage to the common source line SL. While the negative voltage VNEG is applied to the common source line SL, the operation circuit may apply the drain select voltage VDSL to the drain select line DSL to turn on the drain select transistor DST of the selected memory string. The ground voltage may be applied to the drain select line of the non-selected memory string. Also, while the negative voltage VNEG is applied to the common source line SL, the operation circuit applies a read voltage VWL or a verify voltage VWL to the selected word line Sel. WL. Also, while the negative voltage VNEG is applied to the common source line SL, the operation circuit applies a pass voltage VPASS to the non-selected word lines Unsel. WL.

Also, before start of the read operation or the verify operation, the operation circuit may perform an operation of transmitting a negative voltage to vertical channel layers of the memory cells C0 to Cn. In order to perform the above, the operation circuit may apply a source select voltage VSSL to the source select line SSL so as to turn-on the source select transistor for a predetermined period.

Here, all of a voltage of the bit line BL, the connect signal PBSENSE, and the read signal READ may be maintained at a ground level.

In a second period T2, the operation circuit may perform a precharge operation of the bit line BL. Here, the operation circuit may apply the ground voltage to the source select line SSL to turn off the source select transistor SST. The operation circuit may apply a read voltage VWL or a verify voltage VWL to the selected word line Sel. WL, and apply a pass voltage VPASS to the non-selected word lines Unsel. WL.

In the PB 410, when the sensing node S0 is precharged by a power voltage VCC through a transistor P101, and the connect signal PBSENSE at a precharge level VPRE is applied, the bit line BL is precharged to a low level VPRE-Vth. The low level VPRE-Vth is smaller than the precharge level VPRE by a threshold voltage Vth of a transistor N101. Here, since the read signal READ is maintained at the ground level, data of the latch LAT may not be changed although the sensing node S0 is precharged.

During the precharge operation of the bit line BL, the operation circuit may apply the negative voltage VNEG to the common source line SL. Also, during the precharge operation of the bit line BL, the operation circuit may electrically connect or couple channel layers of memory cells C0 to C15 to the bit lines BL. In order to perform the above, the operation circuit may apply the drain select voltage VDSL to the drain select line DSL to turn on the drain select transistor DST.

In a third period T3, the operation circuit may perform an evaluation operation applying operating voltages VWL and VPASS to memory cells C0 to C15. In order to perform the evaluation operation, the operation may apply a positive read voltage VWL or the verify voltage VWL to the selected word line Sel. WL, and apply the pass voltage VPASS to the non-selected word lines Unsel. WL.

During the evaluation operation, the operation circuit may apply the negative voltage VNEG to the common source line SL. Also, the operation circuit may apply positive select voltages VDSL and VSSL to the select lines DSL and SSL to turn on the select transistors DST and SST. Thus, channel layers of the memory cells may be electrically connected or coupled to the bit line BL and the common source line SL.

When the threshold voltage of the memory cell connected or coupled to the selected word line Sel. WL is greater than a level of the read voltage VWL or the verify voltage VWL, a current path from the bit line BL to the common source line SL is blocked, thereby maintaining an electric potential ‘A’ in the bit line BL. In contrast, a threshold voltage of the memory cell connected or coupled to the selected word line Sel. WL is smaller than the level of the read voltage VWL or the verify voltage VWL, a current path is generated from the common source line SL to the bit line BL, thereby decreasing electric potential ‘B’ in the bit line BL.

Then, a connect signal PBSENSE at a sensing level Vsen is applied to the transistor N101 of the connection circuit 411 included in the PB 410. When the bit line BL is maintained at a high voltage ‘A’, an electric potential of the sensing node S0 which is precharged by the transistor P101 is maintained. When an electric potential ‘B’ of the bit line BL is decreased, an electrical potential of the sensing node S0 precharged by the transistor P101 also decreases. The transistor N113 is turned off by the electric potential. The electric potential is lowered by the sensing node S0.

In a fourth period T4, the operation circuit performs a sensing operation of sensing voltage variation of the bit line. During the sensing operation, the operation circuit may apply a negative voltage VNEG to the common source line SL. Here, in order to turn off the source select transistor SST, the operation circuit may apply the ground voltage to the source select line SSL. That is, the sensing operation may be performed while the channel layers of the memory cells are electrically disconnected from the common source line SL. However, a positive drain select voltage VDSL is applied to the drain select line DSL by the operation circuit, and thus, the channel layers of the memory cells may be electrically connected or coupled to the bit line BL.

In order to perform the sensing operation, the operation circuit applies a positive read signal READ to turn on a transistor N15 of the PB 410. When the bit line BL is maintained at the high potential ‘A’, all of the transistors N113 and N115 are turned on by the potential ‘A’ of the bit line BL and the read signal READ, and the inversion output terminal QB of the latch LAT is electrically connected or coupled to a ground terminal. Thus, a potential of the non-inversion output terminal QA of the latch LAT is changed from a low level to a high level. When the bit line BL maintains the low potential ‘B’, the transistor N113 is turned off by the potential ‘B’ of the bit line BL, and thus, potentials of the output terminals QA and QB of the latch LAT are not changed although the transistor N115 is turned on by the read signal READ.

In a fifth period T5, a discharge operation is performed. That is, potentials of the select lines DSL and SSL, the word lines Sel. WL and Unsel. WL, the bit line BL, and the common source line SL are at ground levels. The connect signal PBSENSE and the read signal READ are also at low levels in the PB 410.

According to the above, since the read operation or the verify operation is performed while a negative voltage is applied to the common source line, a cell current may be increased although a size of the transistor is not increased. Thus, operation characteristics and reliability may be improved.

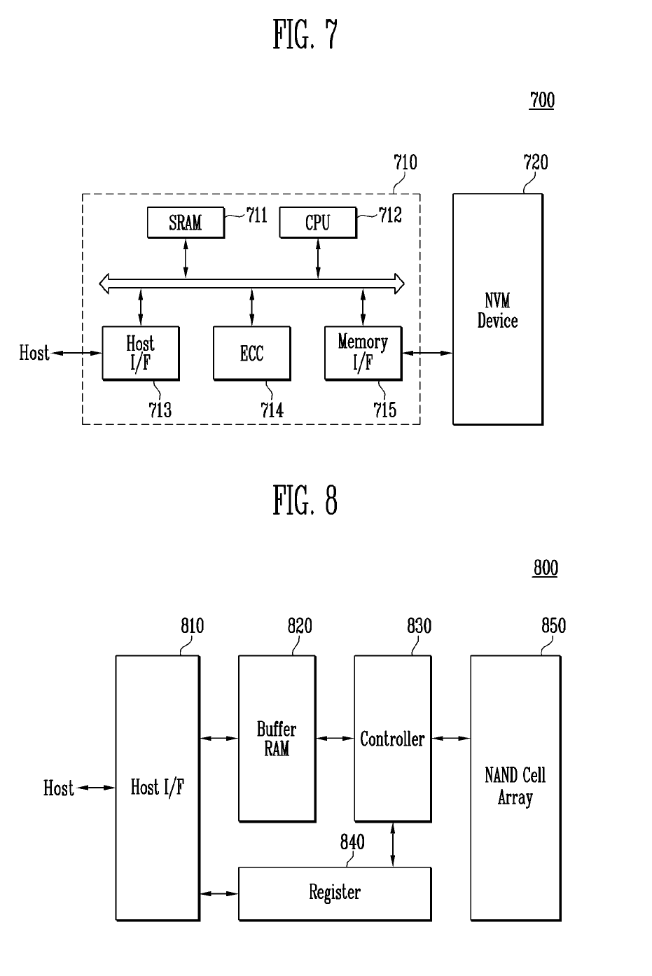

FIG. 7 is a block diagram illustrating a representation of a memory system according to an embodiment.

Referring to FIG. 7, a memory system 700 according to an embodiment may include a nonvolatile memory (NVM) device 720 and a memory controller 710. The NVM device 720 may correspond to the semiconductor device including the memory string illustrated in FIGS. 2A or 4A and the operation circuits illustrated in FIG. 1.

The memory controller 710 may be configured to control the NVM device 720. The NVM device 720 may be combined with the memory controller 710, and used for a memory card or a semiconductor disk device such as a solid state disk (SSD). An SRAM 711 is used as an operational memory of a central processing unit (CPU) 712. A host interface 713 may include a data exchange protocol of a host Host coupled to the memory system 700. An error correcting block (ECC) 714 detects and corrects an error in the data read from a cell area of the NVM device 720. A memory interface 715 interfaces with the NVM device 720 of the present application. The CPU 712 performs overall control operations for exchange data of the memory controller 710.

Although not illustrated in FIG. 7, a person skilled in the art will understand that the memory system 700 according to an embodiment of the present application may further include a ROM (not illustrated) configured to store code data for interfacing with the host Host, and/or the like. The NVM device 720 may be provided as a multi-chip package having a plurality of flash memory chips. The memory system 700 according to an embodiment of the present application may be provided as a highly reliable storage medium having improved operation characteristics. In particular, the flash memory device according to an embodiment of the present application may be included in a memory system such as a semiconductor disk device (an SSD). In these examples, the memory controller 710 may be configured to communicate with the outside (for example, the host Host) through at least one of various interface protocols such as a USB, a MMC, a PCI-E, a SATA, a PATA, an SCSI, an ESDI, an IDE, etc.

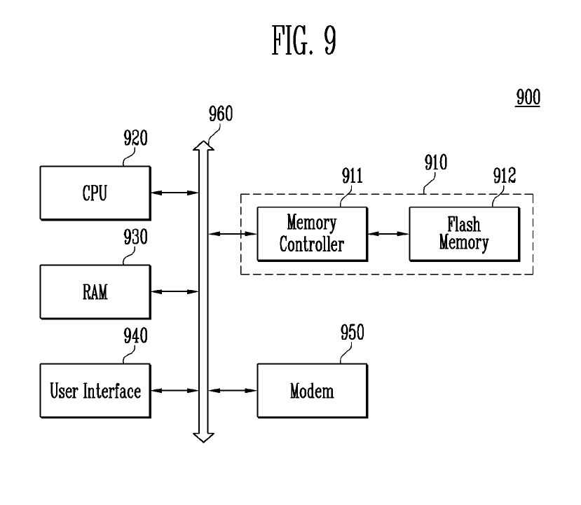

FIG. 8 is a block diagram illustrating a representation of a fusion memory device or a representation of a fusion memory system configured to perform a program operation according to the above-mentioned embodiments. For example, technical characteristics of the present application may be applied to an OneNAND flash memory device 800 as a fusion memory device.

The OneNAND flash memory device 800 may include a host interface 810 configured to exchange various types of information with devices using different protocols, a buffer RAM 820 including a code configured to drive the memory device or temporarily store data, a controller 830 configured to control a read operation, a program operation, and all states in response to a control signal and a command provided from the outside, a register 840 configured to store data such as the command, and an address, a configuration for defining a system operation environment inside the memory device, and/or the like, and a NAND flash cell array 850 including an operation circuit having a nonvolatile memory cell and a PB. A memory array including the memory strings illustrated in FIG. 2A or FIG. 4A may be applied to a memory array of the NAND flash cell array 850.

FIG. 9 is a block diagram illustrating a representation of a computing system including a flash memory device 912 according to an embodiment.

The computing system 900 according to the embodiments may include a CPU 920, a RAM 930, a user interface 940, a modem 950 such as a baseband chipset, and a memory system 910, which are all electrically connected or coupled to a system bus 960. When the computing system 900 is a mobile device, a battery (not illustrated) configured to supply an operating voltage to the computing system 900 may be additionally provided. Although not illustrated in FIG. 9, a person skilled in the art will understand that, in the computing system 900 according to an embodiment of the present application, an application chipset, a camera image processor (CIS), a mobile DRAM, and/or the like may be further provided. The memory system 910, for example, may be included in a solid state drive/disk (SSD) using the nonvolatile memory device described in FIGS. 1 to 6 so as to store data, or the memory system 910 may be provided to a fusion flash memory (for example, the OneNAND flash memory).

According to the embodiments of the present application, operation characteristics may be improved.

The present application is explained with reference to the above examples of embodiments, it will be apparent to those skilled in the art that various modifications can be made to the above-described examples of embodiments of the present application without departing from the spirit or scope of the disclosure. Here, the essential technical scope of the present application is disclosed in the appended claims, and it is intended that the present application cover all such modifications provided they come within the scope of the claims and their equivalents.

What is claimed is:

1. A semiconductor device comprising:
a memory string coupled between a bit line and a common source line and configured to include a drain select transistor, memory cells, and a source select transistor, the drain select transistor configured to operate based on a voltage applied to a drain select line, the memory cells configured to operate based on a voltage applied to word lines, and the source select transistor configured to operate based on a voltage applied to a source select line; and
an operation circuit configured to perform a read operation or a verify operation of the memory cells,
wherein the operation circuit is configured to apply a negative voltage to the common source line during the read operation or the verify operation.

2. The semiconductor device of claim 1, wherein the operation circuit is configured to apply the negative voltage to the common source line before the read operation or the verify operation is started.

3. The semiconductor device of claim 1, wherein the operation circuit is configured to apply a drain select voltage to the drain select line to turn on the drain select transistor while the negative voltage is applied to the common source line.

4. The semiconductor device of claim 1, wherein the operation circuit is configured to apply the negative voltage to a channel layer of the memory cells before the bit line is precharged to perform the read operation or the verify operation.

5. The semiconductor device of claim 4, wherein the operation circuit applies a source select voltage to the source select line to turn on the source select transistor for a predetermined period to transmit the negative voltage to the channel layer.

6. The semiconductor device of claim 4, wherein the operation circuit is configured to apply a read voltage or a verify voltage to the word lines while the negative voltage is applied to the common source line.

7. A semiconductor device comprising:
a memory string including memory cells coupled between a bit line and a common source line; and
an operation circuit configured to perform a precharge operation for precharing the bit line, an evaluation operation for applying an operating voltage to the memory cells, and a sensing operation for sensing a voltage variation of the bit line,
wherein the operation circuit is configured to apply a negative voltage to the common source line during the sensing operation.

8. The semiconductor device of claim 7, wherein the operation circuit is configured to electrically couple channel layers of the memory cells to the bit line during the sensing operation.

9. The semiconductor device of claim 7, wherein the operation circuit is configured to apply a negative voltage to the common source line during the precharge operation.

10. The semiconductor device of claim 7, wherein the operation circuit is configured to electrically couple channel layers of the memory cells to the bit line during the precharge operation.

11. The semiconductor device of claim 7, wherein the operation circuit is configured to apply a negative voltage to the common source line during the evaluation operation.

12. The semiconductor device of claim 7, wherein the operation circuit is configured to electrically couple channel layers of the memory cells to the bit line and the common source line during the evaluation operation.

13. The semiconductor device of claim 7, wherein the operation circuit is configured to apply a read voltage or a verify voltage to a selected memory cell and apply a pass voltage to non-selected memory cells during the precharge operation, the evaluation operation, and the sensing operation.

14. The semiconductor device of claim 7, wherein the operation circuit is configured to electrically couple channel layers of the memory cells to the bit line while the negative voltage is applied to the common source line.

15. The semiconductor device of claim 7,
wherein the operation circuit is configured to electrically couple the common source line to channel layers of the memory cells before the precharge operation is performed, and
wherein the negative voltage is applied to the common source line.

16. A semiconductor device comprising:
a first vertical channel layer coupled between a pipe channel layer and a common source line;
a plurality of first conductive layers located between the pipe channel layer and the common source line and surrounding the first vertical channel layer at different heights of the first vertical channel layer forming at least one memory cell;
a second vertical channel layer coupled between the pipe channel layer and a bit line; and
a plurality of second conductive layers located between the pipe channel layer and the bit line and surrounding the second vertical channel layer at different heights of the second vertical channel layer forming at least one memory cell;
wherein a negative voltage is applied to the common source line during a read operation or a verify operation of the at least one memory cell.

17. The semiconductor device of claim 16, further comprising:
an operation circuit configured to perform the read operation or the verify operation of the at least one memory cell.

18. The semiconductor device of claim 16,
wherein the first vertical channel layer includes polysilicon, and
wherein the second vertical channel layer includes polysilicon.

19. The semiconductor device of claim 17, wherein the operation circuit is configured to apply the negative voltage to the common source line before starting the read operation or starting the verify operation.
